(19) United States
(12) Patent Application Publication
(10) Pub. No.: US 2008/0278201 A1
(43) Pub. Date: Nov. 13, 2008

(54) Buffering circuit of semiconductor device

(75) Inventor: Jun-Woo Lee, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 12/005,954

(22) Filed: Dec. 28, 2007

(30) Foreign Application Priority Data
May 9, 2007 (KR) 2007-0045017

(51) Int. Cl. H03K 3/00

(52) U.S. Cl. 327/108; 327/112

(57) ABSTRACT

A buffering circuit of a semiconductor device includes: a first buffer configured to receive a first power voltage and a second power voltage as driving power voltages to buffer an input signal; a power supplier configured to adjust supply amounts of the first and second power voltages in response to a plurality of driving power signals to supply first and second driving power voltages; and a second buffer configured to receive the first and second driving power voltages, and to buffer an output signal of the first buffer.

### CROSS-REFERENCE TO RELATED APPLICATIONS

The present invention claims priority of Korean patent application number 10-2007-0045017, filed on May 9, 2007, which is incorporated by reference in its entirety.

### BACKGROUND OF THE INVENTION

The present invention relates to semiconductor design technology, and more particularly, to a buffering circuit of a semiconductor device with high-frequency performance, which can maintain a cross point and a duty cycle constantly in spite of process variations.

Semiconductor devices are fabricated through various semiconductor technologies such as silicon wafer processing technology and logic design technology. A final product of the semiconductor fabrication process is a plastic package type chip having different logics and functions depending on its purpose. Most semiconductor chips are mounted on a printed circuit board (PCB) which is an essential element in system configuration, and relevant driving voltages are applied to the chips.

All the semiconductor devices including semiconductor memories operate by inputting/outputting specific signals therethrough. That is, a combination of the input signals determines whether the semiconductor device operates or not and its operation mechanism, and operation results are then outputted according to activation/deactivation of signals. An output signal of one semiconductor device may be used as an input signal of another semiconductor device even in the same system.

Hereinafter, a device for buffering such signals and outputting them will be described with reference to the accompanying drawings.

FIG. 1 is a circuit diagram of a conventional buffering circuit of a semiconductor device.

Referring to FIG. 1, the conventional buffering circuit includes even number of inverters connected in series, for buffering an input signal IN to output an output signal OUT.

For reference, a capacitor C1 connected to an output node represents a load connected to the output node.

A signal of the output node may be illustrated in an eye-diagram when random data is applied as the input signal IN. Using the analysis of the eye-diagram, it can be confirmed whether or not the output signal OUT has a desired duty cycle and a cross point. In general, a p-n ratio, which is a size ratio of a PMOS transistor to an NMOS transistor included in the inverters in the buffering circuit of FIG. 1, is adjusted so as to achieve a duty cycle of 50% and a cross point of a center level.

If the cross-point of the output signal OUT of the DRAM is distorted, a timing margin decreases correspondingly. Therefore, it is very important to maintain the duty cycle of the output signal OUT constantly. An operating frequency was not so high in the existing semiconductor device, and hence a duty cycle variation caused by process variation was not considered very seriously. Accordingly, the crossing point and the duty cycle are adjusted by optimizing only a p-n ratio without any special action.

However, as the operating frequency is increasing and the timing margin is decreasing gradually, the above-described method of adjusting the p-n ratio is not effective any longer. Particularly, under slow PMOS transistor-fast NMOS transistor (SF) condition or fast PMOS transistor-slow NMOS transistor (FS) condition, the cross point is distorted in an opposite direction to the case of typical PMOS transistor-typical NMOS transistor (TT) condition. Therefore, it is difficult to achieve the effectiveness only through the adjustment of the p-n ratio. Specifically, it is possible to obtain satisfactory results under slow PMOS transistor-slow NMOS transistor (SS) condition, the TT condition, and fast PMOS transistor-fast NMOS transistor (FF) condition, by using a fixed p-n ratio solely. However, because the PMOS transistor has an opposite characteristic to the NMOS transistor under the SF or FS condition, it is hard to adjust the cross point to the center level only by using the fixed p-n ratio. Particularly, the conventional buffering circuit made use of an inverter chain configured with an even number of inverters under the FS/SF conditions to offset the distortion in some degree but it is insufficient to offset the distortion of the cross point in the case where a system requires higher and higher frequency performance.

Therefore, in the conventional buffering circuit, the duty cycle and the cross point of the output signal OUT are susceptible to be affected by process variations, leading to the distortion problem. In particular, it is difficult to secure high-frequency performance because the distortion is too severe under the SF or FS condition.

### SUMMARY OF THE INVENTION

Embodiments of the present invention are directed to providing a buffering circuit of a semiconductor device with high-frequency performance, which can maintain a cross point and a duty cycle constantly in spite of process variations.

In accordance with an aspect of the present invention, there is provided a buffering circuit of a semiconductor device, including: a first buffer configured to receive a first power voltage and a second power voltage as driving power voltages to buffer an input signal; a power supplier configured to adjust supply amounts of the first and second power voltages in response to a plurality of driving power signals to supply first and second driving power voltages; and a second buffer configured to receive the first and second driving power voltages, and to buffer an output signal of the first buffer.

In accordance with another aspect of the present invention, there is provided a semiconductor device, including: a first buffer configured to receive a first power voltage and a second power voltage as driving power voltages to buffer an input signal; a ZQ calibration block configured to generate a plurality of first impedance adjusting codes and a plurality of second impedance adjusting codes corresponding to a resistance of a ZQ-resistor; a power supplier configured to adjust supply amounts of the first and second power voltages to supply first and second driving power voltages in response to the first and second impedance adjusting codes; and a second buffer configured to receive the first and second driving power voltages, and to buffer an output signal of the first buffer.

### BRIEF DESCRIPTION OF THE DRAWINGS

FIG. 1 is a circuit diagram of a conventional buffering circuit of a semiconductor device.

FIG. 2 is a circuit diagram illustrating a buffering circuit of a semiconductor device in accordance with an embodiment of the present invention.

FIGS. 3A and 3B are graphs comparing an eye-diagram of signals at output nodes of the conventional buffering circuit with that of the buffering circuit in the semiconductor device of FIG. 2 under an SF condition.

FIGS. 4A and 4B are graphs comparing an output eye-diagram of the conventional buffering circuit and that of the buffering circuit of the present invention under an FS condition.

FIG. 5 is a block diagram illustrating a buffering circuit of a semiconductor device in accordance with another embodiment of the present invention.

### DESCRIPTION OF SPECIFIC EMBODIMENTS

Hereinafter, a buffering circuit of a semiconductor device in accordance with the present invention will be described in detail with reference to the accompanying drawings.

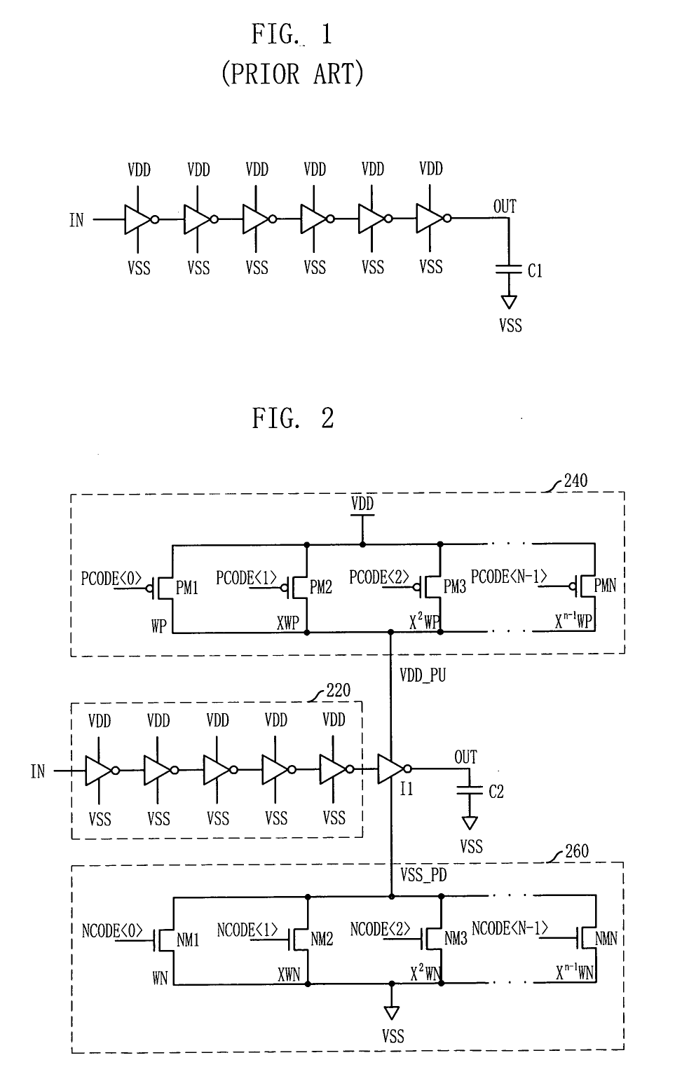

FIG. 2 is a circuit diagram illustrating a buffering circuit of a semiconductor device in accordance with an embodiment of the present invention.

Referring to FIG. 2, the buffering circuit includes a buffer 220, first and second power supplier 240 and 260 and an inverter I1. The buffer 220 receives a power voltage VDD and a ground voltage VSS as driving power voltages to buffer an input signal IN. The power supplier 240 and 260 adjusts supply amounts of the power voltage VDD and the ground voltage VSS in response to a plurality of pull-up driving power signals PCODE<0:N-1> and a plurality of pull-down driving power signals NCODE<0:N-1> to supply pull-up and pull-down driving power voltages VDD_PU and VSS_PD. The inverter I1 inverts the output of the buffer 220 to output the inverted signal as an output signal OUT, and is driven by the pull-up and pull-down driving power voltages VDD_PU and VSS_PD.

The buffer 220 includes a plurality of inverters connected in series so as to receive the power voltage and the ground voltage to buffer the input signal IN.

The first driving power voltage supplier 240 is configured to adjust the supply amount of the power voltage VDD to supply the pull-up driving power voltage VDD_PU in response to the plurality of pull-up driving power signals PCODE<0:N-1>, and the second driving power voltage supplier 260 is configured to adjust the supply amount of the ground voltage VSS to supply the pull-down driving power voltage VSS_PD in response to the plurality of pull-down driving power signals NCODE<0:N-1>.

The first driving power voltage supplier 240 includes first through N-th PMOS transistors PM1 through PMN which are connected in parallel between a supply terminal of the power voltage VDD and a supply terminal of the pull-up driving power voltage VDD_PU and enabled in response to a corresponding one of the pull-up driving power signals PCODE<0:N-1>, respectively. Herein, the first through N-th PMOS transistors PM1 through PMN may have the same size or have a multiple-size relation thereamong.

The second driving power voltage supplier 260 includes first through N-th NMOS transistors NM1 through NMN which are connected in parallel between a supply terminal of the pull-down driving power voltage VSS_PD and a supply terminal of the ground voltage VSS and enabled in response to the corresponding pull-down driving power signals NCODE<0:N-1>, respectively. Herein, the first through N-th NMOS transistors NM1 through NMN may have the same size or have a multiple-size relation thereamong.

For reference, the buffering circuit of the present invention may further include another buffer which is provided with at least an inverter configured to be driven by the full-up and pull-down driving power voltages VDD_PU and VSS_PD for buffering the output signal of the buffer 220.

A capacitor C2 connected to an output node simply represents a load connected to the output node.

In FIG. 2, it is illustrated that reference symbols “WN” and “WP” denote sizes of the NMOS and PMOS transistors. In particular, the reference symbols “X”, “WN” and “WP” are optimized values obtained through simulation.

Therefore, at least one inverter I1 of the plurality of inverters is an active inverter capable of adjusting a crossing point and a duty cycle of the output signal OUT in the semiconductor device in accordance with the present invention. That is, the active inverter I1 receives the adjusted driving power voltages VDD_PU and VSS_PD by the plurality of pull-up driving power signals PCODE<0:N-1> and the plurality of pull-down driving power signals NCODE<0:N-1>. Hence, it is possible to adjust the crossing point and the duty cycle of the output signal OUT by adjusting the supply amounts of the driving power voltages VDD_PU and VSS_PD using the pull-up driving power signals PCODE<0:N-1> and the pull-down driving power signals NCODE<0:N-1>.

For example, if the output signal OUT is slow outputted, a load resistance can be decreased by increasing the number of activation times of each of the pull-up driving power signals PCODE<0:N-1> and the pull-down driving power signals NCODE<0:N-1>. On the contrary, if the output signal OUT is fast outputted, the load resistance can be increased by decreasing the number of activation times of each of the pull-up driving power signals PCODE<0:N-1> and the pull-down driving power signals NCODE<0:N-1>. In this manner, driving force to supply the pull-up and pull-down driving power voltages VDD_PU and VSS_PD are controlled so that the load resistance is calibrated to adjust the supply amount of the pull-up and pull-down driving power voltages VDD_PU and VSS_PD.

For reference, if the first through N-th PMOS transistors PM1 through PMN and the first through N-th NMOS transistors NM1 through NMN which are controlled by the pull-up driving power signals PCODE<0:N-1> and the pull-down driving power signals NCODE<0:N-1>, respectively, have different sizes, it is possible to selectively enable only the PMOS transistor or the NMOS transistor having a desired load resistance.

Consequently, it is possible to adjust the crossing point to have a center level and the duty cycle to be 50% through the calibration of the load resistance even during process variations.

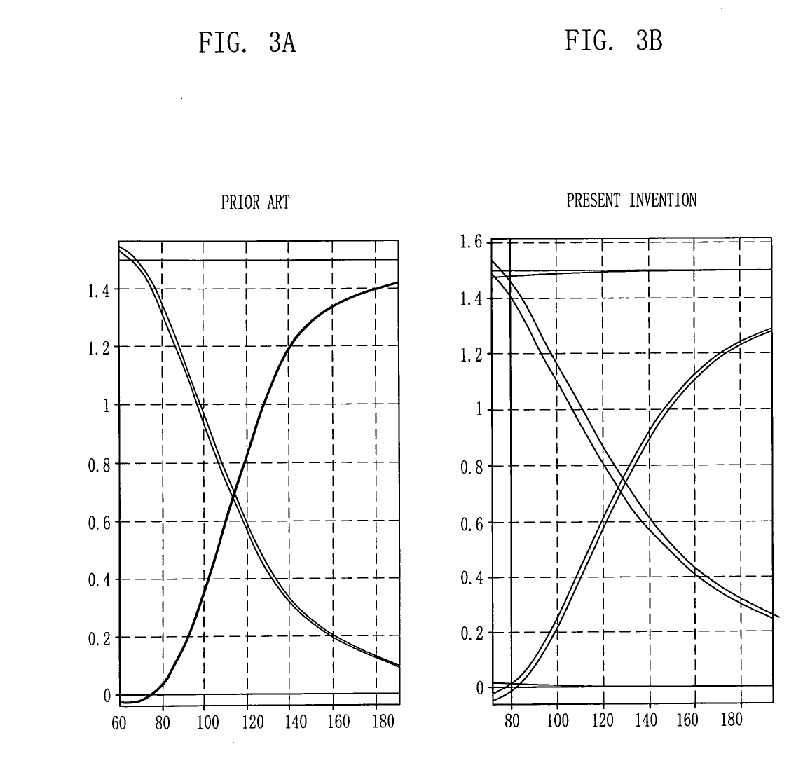

FIGS. 3A and 3B are graphs comparing an eye-diagram of signals at output nodes of the conventional buffering circuit (FIG. 3A) with that of the buffering circuit in the semiconductor device of FIG. 2 under an SF condition (FIG. 3B).

Particularly, output eye-diagrams are compared with each other under the SF condition. FIG. 3A, illustrates the eye-diagram of the conventional buffering circuit of FIG. 1, and FIG. 3B illustrates the eye-diagram of the inventive buffering circuit of FIG. 2.

As shown in FIGS. 3A and 3B, it can be observed that the cross point of the eye-diagram in accordance with the present invention is close to a center level under the SF condition in comparison with the conventional art.

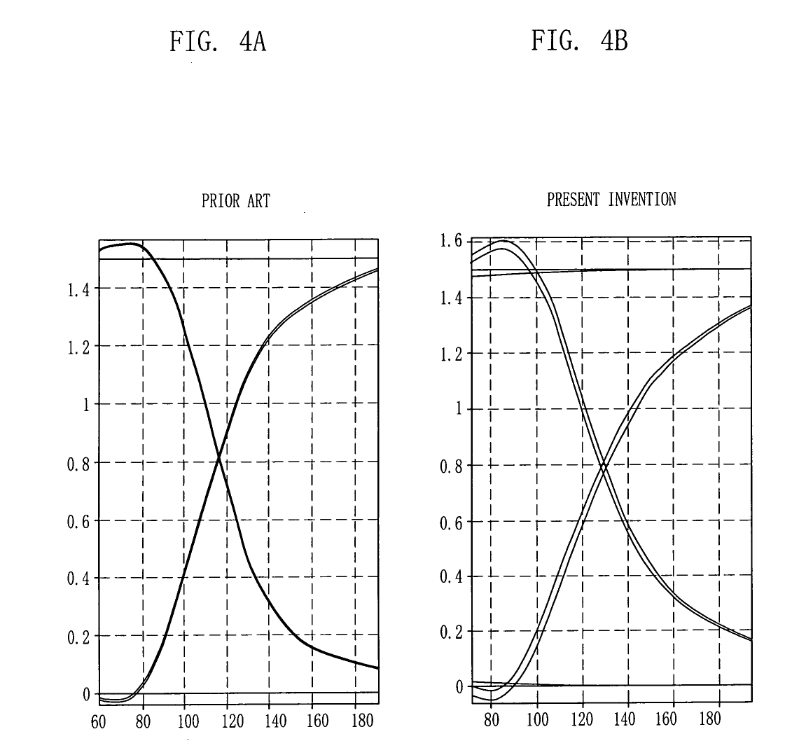

FIGS. 4A and 4B are graphs comparing an output eye-diagram of the conventional buffering circuit (FIG. 4A) and that the buffering circuit of the present invention under an FS condition (FIG. 4B).

Even under the FS condition, it can be also observed that the cross point of the eye-diagram in accordance with the present invention (FIG. 4B) is close to a center level compared to that of the conventional art (FIG. 4A).

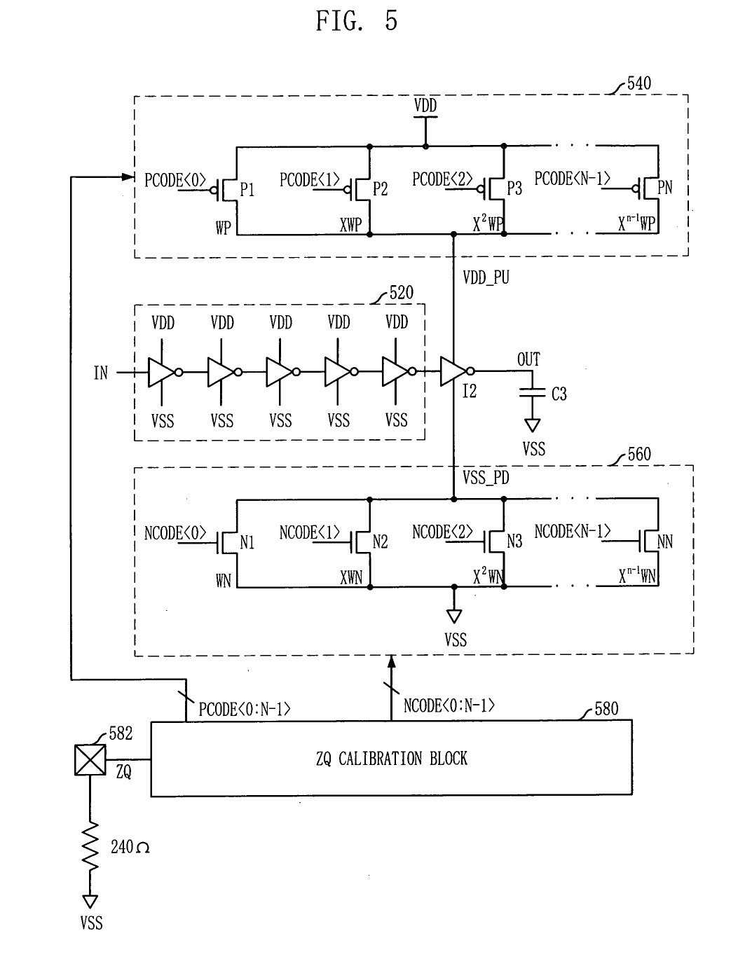

FIG. 5 is a block diagram illustrating a buffering circuit of a semiconductor device in accordance with another embodiment of the present invention.

Referring to FIG. 5, the buffering circuit of this embodiment includes a buffer 520, a ZQ calibration block 580, a first driving power voltage supplier 540, a second driving power voltage supplier 560, and an inverter I2. The buffer 520 configured to buffer an input signal IN includes a plurality of inverters which are connected in series and receive a power voltage VDD and a ground voltage VSS as driving power voltages. The ZQ calibration block 580 generates a plurality of pull-up driving power signals PCODE<0:N-1> and a plurality of pull-down driving power signals NCODE<0:N-1> corresponding to an input resistance of a ZQ resistor. The first driving power voltage supplier 540 adjusts supply amount of the power voltage VDD in response to the plurality of pull-up driving power signals PCODE<0:N-1> to supply a pull-up driving power voltage VDD_PU. The second driving power voltage supplier 560 adjusts the supply amount of the power voltage VSS in response to the plurality of pull-down driving power signals NCODE<0:N-1> to supply a pull-down driving power voltage VSS_PD. The inverter I2 inverts the output of the buffer 520 to output the inverted signal as an output signal OUT, and is driven by the pull-up and pull-down driving power voltages VDD_PU and VSS_PD.

Herein, the ZQ calibration block 580 generates the pluralities of pull-up and pull-down driving power signals PCODE<0:N-1> and NCODE<0:N-1> corresponding to a resistance about 240 Ω of the ZQ resistor connected to a ZQ pad 582 at an initial operation stage and at regular periods in response to a ZQ command ZQC applied from an external chipset.

More specifically, in a standard spec of a DDR2 synchronous memory device, there is a concept of an off chip driver (OCD) calibration control that can calibrate impedance of an output unit of outputting data from a memory device. That is, an OCD calibration control refers to a method of calibrating the impedance of an output driver to be optimized in a present system by measuring a voltage or a current at an external device such as a chipset, which flows through the output driver of the memory device exchanging data. Hence, to meet the specification of the DDR2 synchronous memory device based on JEDEC, the output driver of the memory device must have a function capable of calibrating the impedance. The DRAM memory device may further include an on die termination (ODT) device configured to enable a data signal to be transmitted to another chip without impedance mismatch by calibrating the resistance of an output terminal when the memory device is integrated into a board or the like.

In a standard spec of a DDR3 synchronous memory device, a ZQ calibration is performed for adjusting an impedance of an output driver. As such, the ZQ calibration block 580 is an additional component for generating a plurality of codes so as to calibrate the impedance of the output driver in response to the ZQ command ZQC. Since an impedance adjusting code itself generated by the ZQ calibration block 580 compensates for process variations, it is possible to adjust a p-n ratio in a buffering circuit using the impedance adjusting code. For example, a great number of MOS transistors are turned on using the calibration code if under a slower condition than a typical condition. On the contrary, a small number of MOS transistors are turned on using the calibration code if under a faster condition than the typical condition. Resultingly, the p-n ratio is adaptively varied depending on the process condition.

Therefore, the buffering circuit of this embodiment of FIG. 5 further includes the ZQ calibration block 580 in comparison with the buffering circuit of FIG. 2. The output of the ZQ calibration block 580 is thus used as the pull-up and pull-down driving power signals PCODE<0:N-1> and NCODE<0:N-1>.

Accordingly, the buffering circuits in accordance with the aforesaid embodiments of the present invention further include the active variable inverter capable of calibrating a load resistance, and hence solve the distortion problem of the cross point and the duty cycle of the output signal OUT even under SF and FS process conditions by compensating for the process variations. This provides an advantageous merit of securing a timing margin of a high-speed DRAM.

The circuit of the present invention prevents the duty cycle from being distorted in spite of process variations so that it is also applicable to an output driver of the DRAM.

As described above, a buffering circuit of the present invention further includes an active variable inverter which can calibrate a load resistance to compensate for process variations, which makes it possible to secure a timing margin in a high-speed DRAM in virtue of constant cross point and duty cycle.

While the present invention has been described with respect to the specific embodiments, it will be apparent to those skilled in the art that various changes and modifications may be made without departing from the spirit and scope of the invention as defined in the following claims.

What is claimed is:

1. A buffering circuit of a semiconductor device, comprising:
a first buffer configured to receive a first power voltage and a second power voltage as driving power voltages to buffer an input signal;
a power supplier configured to adjust supply amounts of the first and second power voltages in response to a plurality of driving power signals to supply first and second driving power voltages; and
a second buffer configured to receive the first and second driving power voltages, and to buffer an output signal of the first buffer.

2. The buffering circuit as recited in claim 1, wherein the power supplier comprises:
a first driving power voltage supplier configured to adjust the supply amount of the first power voltage to supply the first driving power voltage in response to a plurality of pull-up driving power signals; and
a second driving power voltage supplier configured to adjust the supply amount of the second power voltage to supply the second driving power voltage in response to a plurality of pull-down driving power signals,
wherein the plurality of driving power signals includes the plurality of pull-up driving power signals, and the plurality of pull-down driving power signals.

3. The buffering circuit as recited in claim 2, wherein the first driving power voltage supplier comprises a plurality of PMOS transistors connected in parallel between a supply terminal of the first power voltage and a supply terminal of the first driving power voltage, and enabled in response to the plurality of pull-up driving power signals.

4. The buffering circuit as recited in claim 3, wherein the plurality of PMOS transistors have one of a same size and a multiple-size relation thereamong.

5. The buffering circuit as recited in claim 2, wherein the second driving power voltage supplier comprises a plurality of NMOS transistors connected in parallel between a supply terminal of the second driving power voltage and a supply terminal of the second power voltage, and enabled in response to the plurality of pull-down driving power signals.

6. The buffering circuit as recited in claim 5, wherein the plurality of NMOS transistors have one of a same size and a multiple-size relation thereamong.

7. The buffering circuit as recited in claim 1, wherein the first buffer comprises a plurality of inverters connected in series for buffering the input signal.

8. The buffering circuit as recited in claim 1, wherein the second buffer comprises at least one inverter configured to receive and buffer the output signal of the first buffer.

9. A semiconductor device, comprising:
a first buffer configured to receive a first power voltage and a second power voltage as driving power voltages to buffer an input signal;
a ZQ calibration block configured to generate a plurality of first impedance adjusting codes and a plurality of second impedance adjusting codes corresponding to a resistance of a ZQ-resistor;
a power supplier configured to adjust supply amounts of the first and second power voltages to supply first and second driving power voltages in response to the first and second impedance adjusting codes; and
a second buffer configured to receive the first and second driving power voltages, and to buffer an output signal of the first buffer.

10. The semiconductor device as recited in claim 9, wherein the ZQ-resistor is coupled to an external pad.

11. The semiconductor device as recited in claim 9, wherein the power supplier comprises:
a first driving power voltage supplier configured to adjust the supply amount of the first power voltage to supply the first driving power voltage in response to the plurality of first impedance adjusting codes; and
a second driving power voltage supplier configured to adjust the supply amount of the second power voltage to supply the second driving power voltage in response to the plurality of second impedance adjusting codes.

12. The semiconductor device as recited in claim 11, wherein the first driving power voltage supplier comprises a plurality of PMOS transistors connected in parallel between a supply terminal of the first power voltage and a supply terminal of the first driving power voltage, and enabled in response to the plurality of first impedance adjusting codes.

13. The semiconductor device as recited in claim 12, wherein the plurality of PMOS transistors have one of a same size and a multiple-size relation thereamong.

14. The semiconductor device as recited in claim 11, wherein the second driving power voltage supplier comprises a plurality of NMOS transistors connected in parallel between a supply terminal of the second driving power voltage and a supply terminal of the second power voltage, and enabled in response to the plurality of second impedance adjusting codes.

15. The semiconductor device as recited in claim 14, wherein the plurality of NMOS transistors have one of a same size and a multiple-size relation thereamong.

16. The semiconductor device as recited in claim 9, wherein the first buffer comprises a plurality of inverters connected in series for buffering the input signal.

17. The semiconductor device as recited in claim 9, wherein the second buffer comprises at least one inverter configured to receive and buffer the output signal of the first buffer.
